(19) United States
(12) Patent Application Publication
(10) Pub. No.: US 2016/0024653 A1
(43) Pub. Date: Jan. 28, 2016

(54) Plasma Source For Rotating Platen ALD Chambers

(71) Applicants: John C. FORSTER, Mt. View, CA (US); Joseph YUDOVSKY, Campbell, CA (US); Applied Materials, Inc., Santa Clara, CA (US)

(72) Inventors: John C. Forster, Mt. view, CA (US); Joseph Yudovsky, Campbell, CA (US)

(73) Assignee: Applied Materials, Inc., Santa Clara, CA (US)

(21) Appl. No.: 14/774,381

(22) PCT Filed: Mar. 14, 2014
(86) PCT No.: PCT/US14/28762

§ 371 Date: Sep. 10, 2015

Related U.S. Application Data
(60) Provisional application No. 61/788,248, filed on Mar. 15, 2013.

(51) Int. Cl. C23C 16/455; C23C 16/458; C23C 16/50

(52) U.S. Cl. CPC C23C 16/45544; C23C 16/50; C23C 16/458; Y10S 901/50

(57) ABSTRACT

Substrate processing chambers and methods for processing multiple substrates generally including an inductively coupled pie-shaped plasma source positioned so that a substrate rotating on a platen will pass through a plasma region adjacent the plasma source.

### FIELD

Embodiments of the present invention generally relate to an apparatus for processing substrates. More particularly, the invention relates to a batch processing platform for performing atomic layer deposition (ALD) and chemical vapor deposition (CVD) on substrates.

### BACKGROUND

The process of forming semiconductor devices is commonly conducted in substrate processing platforms containing multiple chambers. In some instances, the purpose of a multi-chamber processing platform or cluster tool is to perform two or more processes on a substrate sequentially in a controlled environment. In other instances, however, a multiple chamber processing platform may only perform a single processing step on substrates; the additional chambers are intended to maximize the rate at which substrates are processed by the platform. In the latter case, the process performed on substrates is typically a batch process, wherein a relatively large number of substrates, e.g. 25 or 50, are processed in a given chamber simultaneously. Batch processing is especially beneficial for processes that are too time-consuming to be performed on individual substrates in an economically viable manner, such as for ALD processes and some chemical vapor deposition (CVD) processes.

The effectiveness of a substrate processing platform, or system, is often quantified by cost of ownership (COO). The COO, while influenced by many factors, is largely affected by the system footprint, i.e., the total floor space required to operate the system in a fabrication plant, and system throughput, i.e., the number of substrates processed per hour. Footprint typically includes access areas adjacent the system that are required for maintenance. Hence, although a substrate processing platform may be relatively small, if it requires access from all sides for operation and maintenance, the system's effective footprint may still be prohibitively large.

The semiconductor industry's tolerance for process variability continues to decrease as the size of semiconductor devices shrink. To meet these tighter process requirements, the industry has developed a host of new processes which meet the tighter process window requirements, but these processes often take a longer time to complete. For example, for forming a copper diffusion barrier layer conformally onto the surface of a high aspect ratio, 65 nm or smaller interconnect feature, it may be necessary to use an ALD process. ALD is a variant of CVD that demonstrates superior step coverage compared to CVD. ALD is based upon atomic layer epitaxy (ALE) that was originally employed to fabricate electroluminescent displays. ALD employs chemisorption to deposit a saturated monolayer of reactive precursor molecules on a substrate surface. This is achieved by cyclically alternating the pulsing of appropriate reactive precursors into a deposition chamber. Each injection of a reactive precursor is typically separated by an inert gas purge to provide a new atomic layer to previous deposited layers to form a uniform material layer on the surface of a substrate. Cycles of reactive precursor and inert purge gases are repeated to form the material layer to a desired thickness. The biggest drawback with ALD techniques is that the deposition rate is much lower than typical CVD techniques by at least an order of magnitude. For example, some ALD processes can require a chamber processing time from about 10 to about 200 minutes to deposit a high quality layer on the surface of the substrate. In choosing such ALD and epitaxy processes for better device performance, the cost to fabricate devices in a conventional single substrate processing chamber would increase due to very low substrate processing throughput. Hence, when implementing such processes, a continuous substrate processing approach is needed to be economically feasible.

Currently, carousel type processing systems do not provide a uniform plasma treatment because of the path followed by the substrate during processing. Therefore, there is a need in the art for continuous substrate processing with uniform deposition and post-treatment of ALD films.

### SUMMARY

Embodiments of the invention are directed to processing chambers comprising at least one inductively coupled pie-shaped plasma and a substrate support apparatus. The at least one inductively coupled pie-shaped plasma source is positioned along an arcuate path in the processing chamber to generate an inductively coupled plasma in a plasma region adjacent the plasma source. The pie-shaped plasma source has a narrow width at an inner peripheral edge and a larger width at an outer peripheral edge. The pie-shaped plasma source comprises a plurality of conductive rods within the inductively coupled plasma source. The inductively coupled plasma has a substantially uniform plasma density between the narrow inner peripheral edge and the wider outer peripheral edge. The substrate support apparatus is within the processing chamber and is rotatable around a central axis of the processing chamber to move at least one substrate along the arcuate path adjacent the at least one pie-shaped plasma source.

In some embodiments, the conductive rods are radially spaced apart and extend along the width of the inductively coupled pie-shaped plasma source. In one or more embodiments, the spacing between the conductive rods is a function of the width of the pie-shaped plasma source that the conductive rod extends through. In some embodiments, a density of conductive rods is greater toward the inner peripheral edge of the pie-shaped plasma source than at the outer peripheral edge.

In one or more embodiments, the plurality of conductive rods comprises a single rod that repeatedly passes through the pie-shaped plasma source. In some embodiments, each of the conductive rods is a separate rod.

In one or more embodiments, the plurality of conductive rods extend at an oblique angle with respect to radial walls of the pie-shaped plasma source, each conductive rod extending through a length of the pie-shaped plasma source.

In some embodiments, the pie-shaped plasma source further comprises a dielectric layer between the plurality of conductive rods and a region in which plasma is formed. In one or more embodiments, the dielectric layer comprises quartz.

Some embodiments further comprise a plurality of gas distribution assemblies spaced around the central axis of the processing chamber and positioned above the substrate support apparatus. In one or more embodiments, each of the gas distribution assemblies comprises a plurality of elongate gas ports extending in a direction substantially perpendicular to the arcuate path traversed by the at least one substrate/ The plurality of gas ports comprise a first reactive gas port and a second reactive gas port so that a substrate passing the gas distribution assemblies will be subjected to, in order, the first reactive gas port and the second reactive gas port to deposit a layer on the substrate. In one or more embodiments, there are a plurality of inductively coupled pie-shaped plasma sources alternating with the plurality of gas distribution assemblies so that a substrate moving along the arcuate path would be sequentially exposed to a gas distribution assembly and plasma source.

In some embodiments, the substrate support apparatus comprises a susceptor assembly. In some embodiments, the susceptor comprises a plurality of recesses sized to support a substrate. In one or more embodiments, the recesses are sized so that a top surface of the substrate is substantially coplanar with a top surface of the susceptor.

Additional embodiments of the invention are directed to process chambers comprising a plurality of pie-shaped gas distribution assemblies, a plurality of inductively coupled pie-shaped plasma sources and a susceptor. The plurality of pie-shaped gas distribution assemblies are spaced about the processing chamber so that there is a region between each of the gas distribution assemblies. Each of the pie-shaped gas distribution assemblies has an inner peripheral edge and an outer peripheral edge and a plurality of elongate gas ports extending from near the inner peripheral edge to near the outer peripheral edge and having a larger width at the outer peripheral edge than at the inner peripheral edge. The plurality of gas ports comprise a first reactive gas port and second reactive gas port so that a substrate passing the gas distribution assembly will be subjected to, in order, the first reactive gas port and the second reactive gas port to deposit a layer on the substrate. The plurality of inductively coupled pie-shaped plasma sources are spaced about the processing chamber so that at least one inductively coupled pie-shaped plasma source is between each of the plurality of pie-shaped gas distribution assemblies. The inductively coupled pie-shaped plasma sources generate an inductively coupled plasma in a plasma region adjacent the plasma source. The pie-shaped plasma sources have a narrow width at an inner peripheral edge and a larger width at an outer peripheral edge. Each of the pie-shaped plasma sources comprises one or more of a plurality of conductive rods passing through the plasma source and a single conductive rod repeatedly passing through the plasma source. The susceptor comprises a plurality of recesses to support a plurality of substrates. The susceptor is rotatable in a circular path adjacent each of the plurality of gas distribution assemblies and the plurality of inductively coupled pie-shaped plasma sources. The inductively coupled plasma in the plasma region has a substantially uniform plasma density near the narrow inner peripheral edge and the wider outer peripheral edge.

In some embodiments, the plurality of conductive rods are radially spaced apart and extend along the width of the inductively coupled pie-shaped plasma source, wherein the spacing between the conductive rods is a function of the width of a portion of the pie-shaped plasma source that the conductive rod extends through. In one or more embodiments, a density of conductive rods is greater toward the inner peripheral edge of the pie-shaped plasma source than at the outer peripheral edge.

Further embodiments of the invention are directed to cluster tools comprising a central transfer station and at least one processing chamber as described herein. The central transfer station comprises a robot to move substrates between the central transfer station and one or more of a load lock chamber and a processing chamber.

Additional embodiments of the invention are directed to methods of processing a plurality of substrates. A plurality of substrates is loaded onto a substrate support in a processing chamber. The substrate support is rotated to pass each of the plurality of substrates across a gas distribution assembly to deposit a film on the substrate. The substrate support is rotated to move the substrates to a plasma region adjacent an inductively coupled pie-shaped plasma source generating a substantially uniform plasma in the plasma region. Repeating rotations to form a film of desired thickness.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a partial cross-sectional side view of a spatial atomic layer deposition chamber in accordance with one or more embodiment of the invention;

FIG. 2 shows a perspective view of a susceptor in accordance with one or more embodiments of the invention;

FIG. 3 shows a schematic of a pie-shaped gas distribution assembly in accordance with one or more embodiments of the invention;

FIG. 4 is a schematic plan view of a substrate processing system configured with four gas distribution assemblies and four inductively coupled pie-shaped plasma sources with a loading station in accordance with one or more embodiments of the invention;

FIG. 5 is a schematic of a platen rotating a wafer through a pie-shaped plasma region in accordance with one or more embodiment of the invention;

FIG. 6A shows a top view of an inductively coupled pie-shaped plasma source in accordance with one or more embodiments of the invention;

FIG. 6B shows a perspective view of the plasma source of FIG. 6A;

FIG. 7 shows an inductively coupled pie-shaped plasma source with variable spaced RF conductor rods in accordance with one or more embodiments of the invention; and

FIG. 8 shows an inductively coupled pie-shaped plasma source with RF conductor rods extending at oblique angles to the sides of the source in accordance with one or more embodiments of the invention.

### DETAILED DESCRIPTION

Embodiments of the invention provide a substrate processing system for continuous substrate deposition to maximize throughput and improve processing efficiency. The substrate processing system can also be used for pre-deposition and post-deposition plasma treatments.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. For example, in spatially separated

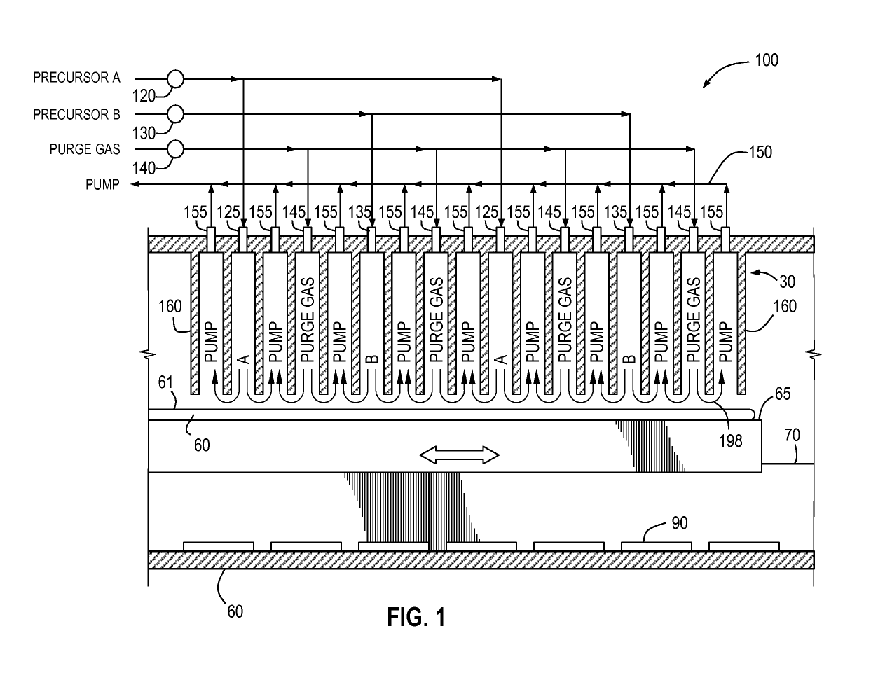

ALD, described with respect to FIG. 1, each precursor is delivered to the substrate, but any individual precursor stream, at any given time, is only delivered to a portion of the substrate. Additionally, reference to depositing on a substrate can mean both a bare substrate and a substrate with one or more films or features deposited or formed thereon.

As used in this specification and the appended claims, the terms “reactive gas”, “precursor”, “reactant”, and the like, are used interchangeably to mean a gas that includes a species which is reactive in an atomic layer deposition process. For example, a first “reactive gas” may simply adsorb onto the surface of a substrate and be available for further chemical reaction with a second reactive gas.

Rotating platen chambers are being considered for atomic layer deposition applications. In such a chamber, one or more wafers are placed on a rotating holder (“platen”). As the platen rotates, the wafers move between various processing areas. In ALD, the processing areas would expose the wafer to precursor and reactants. In addition, plasma exposure may be necessary to properly treat the film or the surface for enhanced film growth, or to obtain desirable film properties. Some embodiments of the invention provide for uniform deposition and post-treatment (e.g., densification) of ALD films when using a rotating platen ALD chamber.

Rotating platen ALD chambers can deposit films by traditional time-domain processes where the entire wafer is exposed to a first gas, purged and then exposed to the second gas, or by spatial ALD where portions of the wafer are exposed to the first gas and portions are exposed to the second gas and the movement of the wafer through these gas streams deposits the layer. While either process type can be employed, rotating platens may be of particular use with spatial processes.

FIG. 1 is a schematic cross-sectional view of a portion of a processing chamber 20 in accordance with one or more embodiments of the invention. The processing chamber 20 is generally a sealable enclosure, which is operated under vacuum or at least low pressure conditions. The system 100 includes a gas distribution assembly 30 capable of distributing one or more gases across the top surface 61 of a substrate 60. The gas distribution assembly 30 can be any suitable assembly known to those skilled in the art, and specific gas distribution assemblies described should not be taken as limiting the scope of the invention. The output face of the gas distribution assembly 30 faces the first surface 61 of the substrate 60.

Substrates for use with the embodiments of the invention can be any suitable substrate. In some embodiments, the substrate is a rigid, discrete, generally planar substrate. As used in this specification and the appended claims, the term “discrete” when referring to a substrate means that the substrate has a fixed dimension. The substrate of one or more embodiments is a semiconductor substrate, such as a 200 mm or 300 mm diameter silicon substrate. In some embodiments, the substrate is one or more of silicon, silicon germanium, gallium arsenide, gallium nitride, germanium, gallium phosphide, indium phosphide, sapphire and silicon carbide.

The gas distribution assembly 30 comprises a plurality of gas ports to transmit one or more gas streams to the substrate 60 and a plurality of vacuum ports disposed between each gas port to transmit the gas streams out of the processing chamber 20. In the embodiment of FIG. 1, the gas distribution assembly 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 injects a continuous (or pulse) stream of a reactive precursor of compound A into the processing chamber 20 through a plurality of gas ports 125. The precursor injector 130 injects a continuous (or pulse) stream of a reactive precursor of compound B into the processing chamber 20 through a plurality of gas ports 135. The purge gas injector 140 injects a continuous (or pulse) stream of a non-reactive or purge gas into the processing chamber 20 through a plurality of gas ports 145. The purge gas removes reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and the precursor injector 130 prior to injecting the precursors into the processing chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high energy light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60, for example, about 0.5 mm or greater from the first surface 61. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads and gas distribution assemblies may be employed.

Atomic layer deposition systems of this sort (i.e., where multiple gases are separately flowed toward the substrate at the same time) are referred to as spatial ALD. In operation, a substrate 60 is delivered (e.g., by a robot) to the processing chamber 20 and can be placed on a shuttle 65 before or after entry into the processing chamber. The shuttle 65 is moved along the track 70, or some other suitable movement mechanism, through the processing chamber 20, passing beneath (or above) the gas distribution assembly 30. In the embodiment shown in FIG. 1, the shuttle 65 is moved in a linear path through the chamber. FIG. 3, as explained further below, shows an embodiment in which wafers are moved in a circular path through a carousel processing system.

Referring back to FIG. 1, as the substrate 60 moves through the processing chamber 20, the first surface 61 of substrate 60 is repeatedly exposed to the reactive gas A coming from gas ports 125 and reactive gas B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the reactive gases or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the substrate surface 110 and around the lower portions of the partitions 160, and finally upward toward the vacuum ports 155. In this manner, each gas may be uniformly distributed across the substrate surface 110. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discrete steps and can occur while the substrate is passing beneath the gas distribution assembly 30 or when the substrate is in a region before and/or after the gas distribution assembly 30.

Sufficient space is generally provided after the gas distribution assembly 30 to ensure complete exposure to the last gas port. Once the substrate 60 has completely passed beneath the gas distribution assembly 30, the first surface 61 has completely been exposed to every gas port in the processing chamber 20. The substrate can then be transported back in the opposite direction or forward. If the substrate 60 moves in the opposite direction, the substrate surface may be exposed again to the reactive gas A, the purge gas, and reactive gas B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are controlled so as not to remove adsorbed precursors from the substrate surface 61. The width between each partition, the number of gas ports disposed on the processing chamber 20, and the number of times the substrate is passed across the gas distribution assembly may also determine the extent to which the substrate surface 61 is exposed to the various gases. Consequently, the quantity and quality of a deposited film may be optimized by varying the above-referenced factors.

Although description of the process has been made with the gas distribution assembly 30 directing a flow of gas downward toward a substrate positioned below the gas distribution assembly, it will be understood that this orientation can be different. In some embodiments, the gas distribution assembly 30 directs a flow of gas upward toward a substrate surface. As used in this specification and the appended claims, the term “passed across” means that the substrate has been moved from one side of the gas distribution assembly to the other side so that the entire surface of the substrate is exposed to each gas stream from the gas distribution plate. Absent additional description, the term “passed across” does not imply any particular orientation of gas distribution assemblies, gas flows or substrate positions.

In some embodiments, the shuttle 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) or in a circular direction (relative to FIG. 3). The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

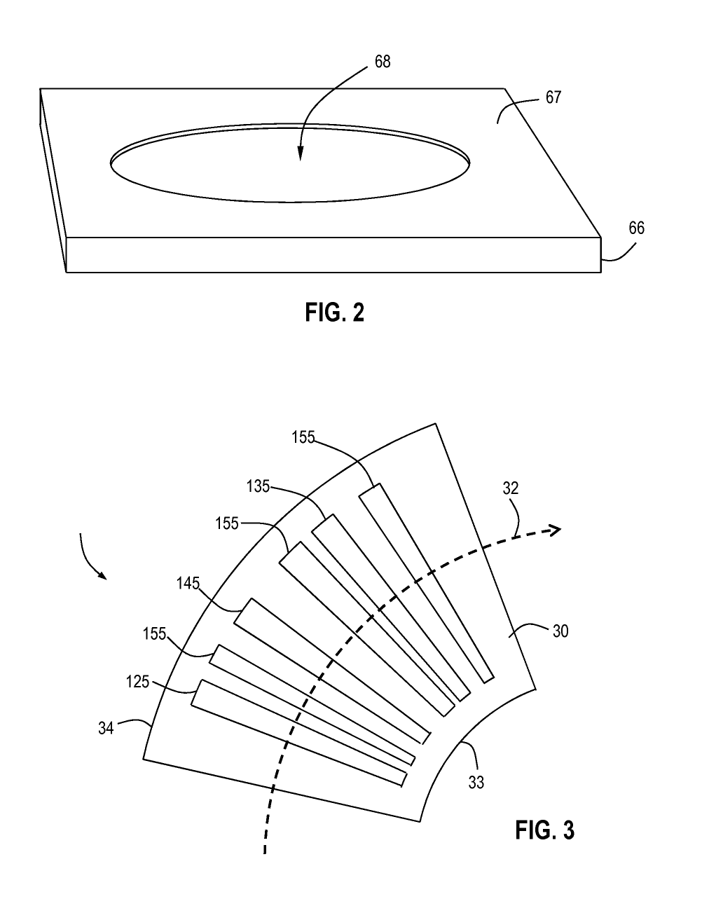

In still another embodiment, the top surface 67 of the susceptor 66 includes a recess 68 to accept the substrate 60, as shown in FIG. 2. The susceptor 66 is generally thicker than the thickness of the substrate so that there is susceptor material beneath the substrate. In some embodiments, the recess 68 is sized such that when the substrate 60 is disposed inside the recess 68, the first surface 61 of substrate 60 is level with, or substantially coplanar with, the top surface 67 of the susceptor 66. Stated differently, the recess 68 of some embodiments is sized such that when a substrate 60 is disposed therein, the first surface 61 of the substrate 60 does not protrude above the top surface 67 of the susceptor 66. As used in this specification and the appended claims, the term “substantially coplanar” means that the top surface of the wafer and the top surface of the susceptor assembly are coplanar within ±0.2 mm. In some embodiments, the top surfaces are coplanar within ±0.15 mm, ±0.10 mm or ±0.05 mm.

FIG. 1 shows a cross-sectional view of a processing chamber in which the individual gas ports are shown. This embodiment can be either a linear processing system in which the width of the individual gas ports is substantially the same across the entire width of the gas distribution plate, or a pie-shaped segment in which the individual gas ports change width to conform to the pie shape. As used in this specification and the appended claims, the term “pie-shaped” is used to describe a body that is a generally circular sector. For example, a pie-shaped segment may be one-quarter of a circle or disc-shaped object. The inner edge of the pie-shaped segment can come to a point or can be truncated to a flat edge or rounded like the sector shown in FIG. 3. FIG. 3 shows a portion of a pie-shaped gas distribution assembly 30. A substrate would be passed across this gas distribution assembly 30 in an arc shape path 32. Each of the individual gas ports 125, 135, 145, 155 have a narrower width near the inner peripheral edge 33 of the gas distribution assembly 30 a and a larger width near the outer peripheral edge 34 of the gas distribution assembly 30. The shape or aspect ratio of the individual ports can be proportional to, or different from, the shape or aspect ratio of the gas distribution assembly 30 segment. In some embodiments, the individual ports are shaped so that each point of a wafer passing across the gas distribution assembly 30 following path 32 would have about the same residence time under each gas port. The path of the substrates can be perpendicular to the gas ports. In some embodiments, each of the gas distribution assemblies comprises a plurality of elongate gas ports which extend in a direction substantially perpendicular to the path traversed by a substrate. As used in this specification and the appended claims, the term “substantially perpendicular” means that the general direction of movement is approximately perpendicular to the axis of the gas ports. For a pie-shaped gas port, the axis of the gas port can be considered to be a line defined as the mid-point of the width of the port extending along the length of the port.

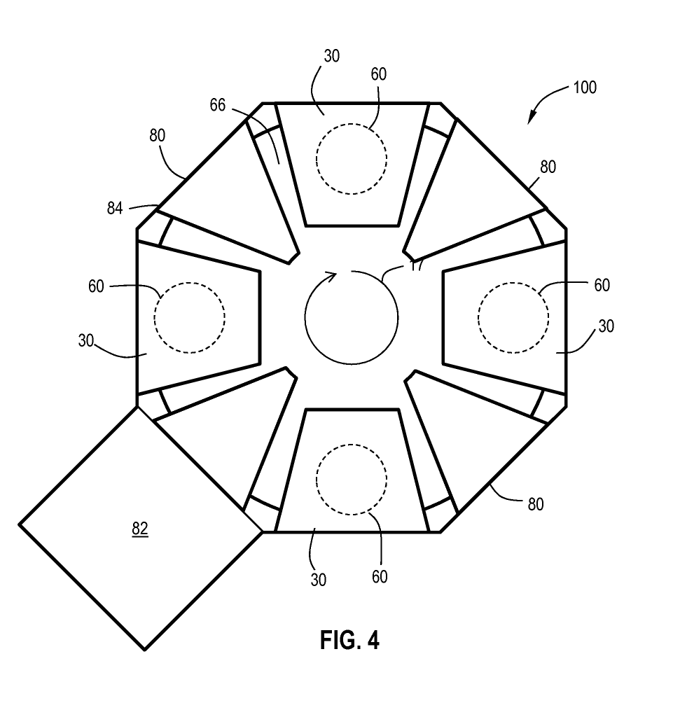

Processing chambers having multiple gas injectors can be used to process multiple wafers simultaneously so that the wafers experience the same process flow. For example, as shown in FIG. 4, the processing chamber 100 has four gas injector assemblies 30 and four wafers 60. At the outset of processing, the wafers 60 can be positioned between the injector assemblies 30. Rotating the susceptor 66 of the carousel by 45° will result in each wafer 60 being moved to an injector assembly 30 for film deposition. An additional 45° rotation would move the wafers 60 away from the injector assemblies 30. This is the position shown in FIG. 4. With spatial ALD injectors, a film is deposited on the wafer during movement of the wafer relative to the injector assembly. In some embodiments, the susceptor 66 is rotated so that the wafers 60 do not stop beneath the injector assemblies 30. The number of wafers 60 and gas distribution assemblies 30 can be the same or different. In some embodiments, there is the same number of wafers being processed as there are gas distribution assemblies. In one or more embodiments, the number of wafers being processed are an integer multiple of the number of gas distribution assemblies. For example, if there are four gas distribution assemblies, there are 4x wafers being processed, where x is an integer value greater than or equal to one.

The processing chamber 100 shown in FIG. 4 is merely representative of one possible configuration and should not be taken as limiting the scope of the invention. Here, the processing chamber 100 includes a plurality of gas distribution assemblies 30. In the embodiment shown, there are four gas distribution assemblies 30 evenly spaced about the processing chamber 100. The processing chamber 100 shown is octagonal, however, it will be understood by those skilled in the art that this is one possible shape and should not be taken as limiting the scope of the invention. The gas distribution assemblies 30 shown are rectangular, but it will be understood by those skilled in the art that the gas distribution assemblies can be pie-shaped segments, like that shown in FIG. 3.

The processing chamber 100 includes a substrate support apparatus, shown as a round susceptor 66 or susceptor assembly. The substrate support apparatus, or susceptor 66, is capable of moving a plurality of substrates 60 beneath each of the gas distribution assemblies 30. A load lock 82 might be connected to a side of the processing chamber 100 to allow the substrates 60 to be loaded/unloaded from the chamber 100.

In some embodiments, the processing chamber comprises a plurality of gas curtains (not shown) positioned between the gas distribution plates 30 and the plasma stations 80. Each gas curtain can creates a barrier to prevent, or minimize, the movement of processing gases from the gas distribution assemblies 30 from migrating from the gas distribution assembly regions and gases from the plasma sources 80 from migrating from the plasma regions. The gas curtain can include any suitable combination of gas and vacuum streams which can isolate the individual processing sections from the adjacent sections. In some embodiments, the gas curtain is a purge (or inert) gas stream. In one or more embodiments, the gas curtain is a vacuum stream that removes gases from the processing chamber. In some embodiments, the gas curtain is a combination of purge gas and vacuum streams so that there are, in order, a purge gas stream, a vacuum stream and a purge gas stream. In one or more embodiments, the gas curtain is a combination of vacuum streams and purge gas streams so that there are, in order, a vacuum stream, a purge gas stream and a vacuum stream.

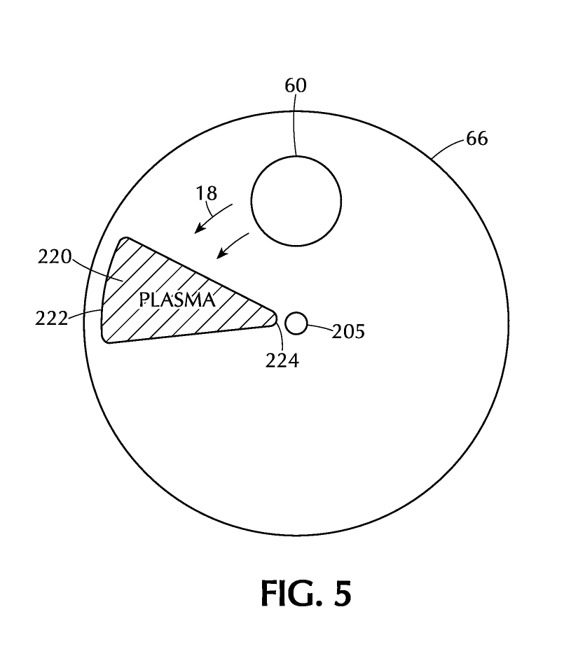

Any plasma treatment will need to occur uniformly across the wafer as it rotates through the plasma region. One potential method is to have a “pie-shaped” (circular sector) plasma region of uniform plasma density. FIG. 5 shows a simple platen structure, also referred to as a susceptor 66 or susceptor assembly, with a single wafer 60. As the susceptor 66 rotates the substrate 60 along an arcuate path 18, the substrate 60 passes through a plasma region 220 which has a pie-shape. Because the susceptor is rotating about the axis 205, different portions of the substrate will have different annular velocities, with the outer peripheral edge of the substrate moving faster than the inner peripheral edge. Therefore, to ensure that all portions of the substrate have about the same residence time in the plasma region, the plasma region is wider at the outer peripheral edge 222 than at the inner peripheral edge 224.

An option for a plasma source is an inductively coupled plasma. Such plasmas have high plasma density and low plasma potentials. An inductively coupled plasma is generated via RF currents in conductors. The RF carrying conductors may be separated from the plasma via a dielectric window, thereby minimizing the possibility of metallic contamination of the film.

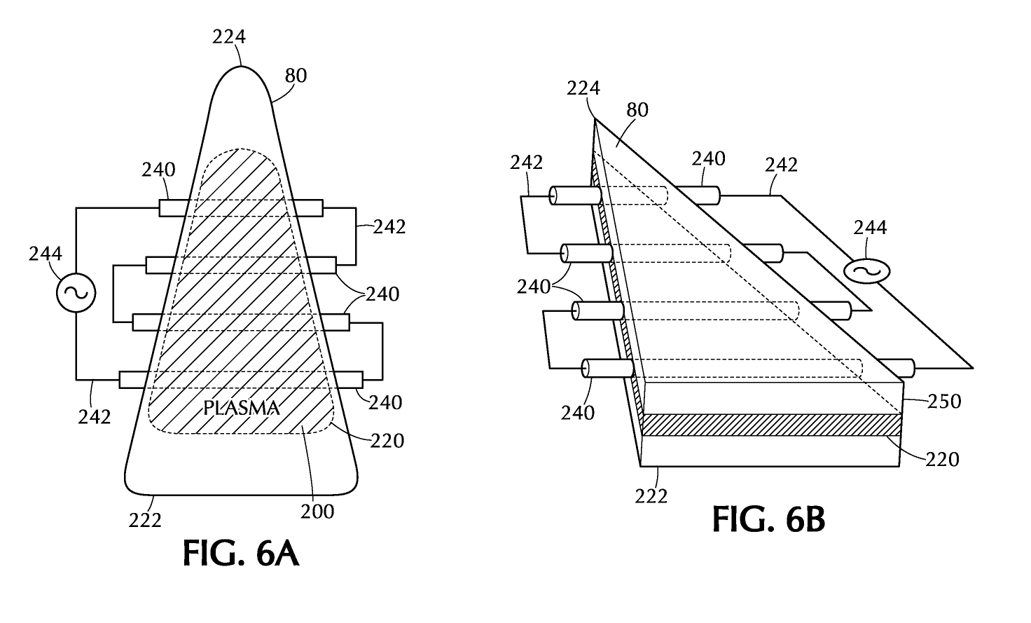

Some embodiments of the invention are directed to processing chambers comprising at least one inductively coupled pie-shaped plasma source 80 positioned along an arcuate path in a processing chamber. FIG. 6A shows a top view of a pie-shaped plasma source 80 with an inductively coupled plasma 200 in a plasma region 220 adjacent the plasma source 80. The pie-shaped plasma source 80 has a narrow width at an inner peripheral edge 224 and a larger, or wider, width at an outer peripheral edge 222.

The pie-shaped plasma source 80 includes a plurality of conductive rods 240 within the inductively coupled plasma source 80. The plurality of conductive rods 240 shown in the Figures are connected by wire 242 to each other so that there is one long string of conductive rods 240 connected to a single power source 244. The power source 244 supplying sufficient current across the conductive rods 240 to create the inductively coupled plasma in the plasma region.

In some embodiments, each conductive rod 240 is connected to its own power source 244 and independently controlled. This requires multiple power sources 244 and control circuits but may also provide greater control over the uniformity of the plasma density.

The conductive rods can be positioned within the plasma region, or in a dielectric layer above the plasma region. In some embodiments, the conductive rods are positioned in the plasma region. In one or more embodiments, the conductive rods are positioned in the plasma region wrapped, or shielded from direct view of the substrate or susceptor surface to prevent sputtering of the conductive rods onto the substrate or susceptor. Wrapping the conductive rods in a dielectric sleeve (e.g., quartz or ceramic) should prevent sputtering of any of the conductive rod material, which could lead to metallic contamination on the wafer. Merely shielding the conductive rods from the plasma region may still allow some of the conductive rods to be sputtered, but should minimize the amount of sputtered material that impacts the wafer.

FIG. 6B shows a perspective view of the pie-shaped plasma source 80 of FIG. 6A. It can be seen that the conductive rods 240 extend along the width of the plasma source 80 and are separated from the plasma region 220 by a dielectric layer 250. The dielectric layer can be made of any suitable dielectric material including, but not limited to, quartz, ceramic and aluminum oxide. The use of some dielectric materials (e.g., quartz) may provide a barrier to potential capacitive coupling between adjacent rods 240.

The conductive rods 240 are radially spaced apart and extend along the width of the plasma source 80. Radially spaced apart means that each adjacent rod is closer to or further from the central axis of the processing chamber. While the substrate will follow an arcuate path, the individual rods 240 can be straight (as shown) or follow the arcuate path.

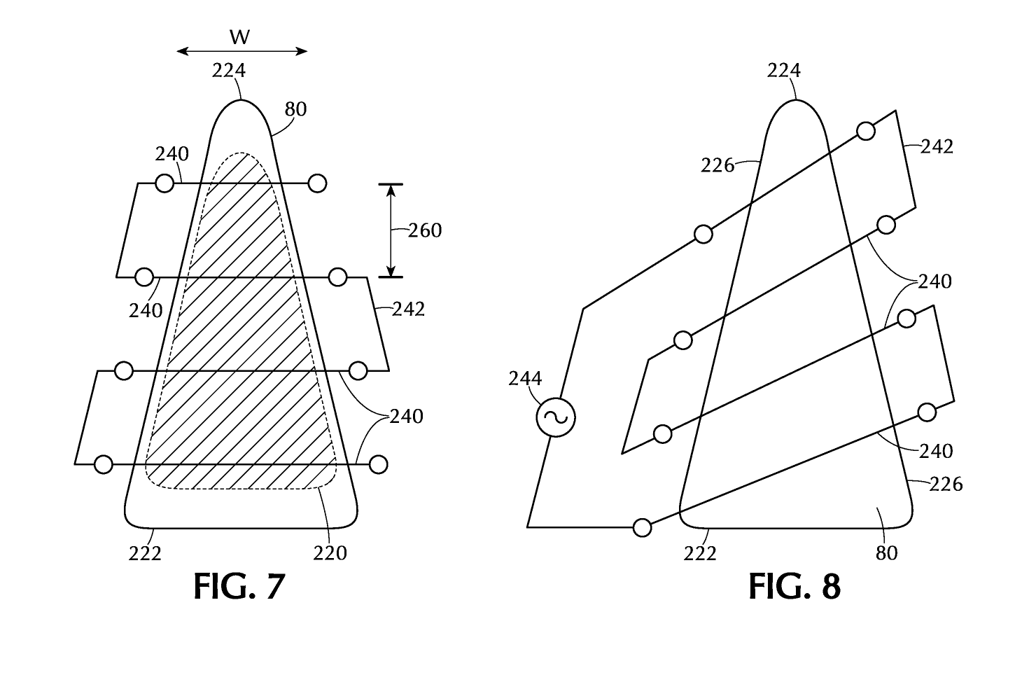

In some embodiments, the inductively coupled pie-shaped plasma sources include a variable arrangement of RF conductors to change the uniformity of the plasma. FIG. 7 shows an arrangement of RF conductors 240 where the rods are arrayed closer together in the narrower portion inner peripheral edge 224 than at the outer peripheral edge 222. Without being bound by any particular theory of operation, it is believed that the closer arrangement of the RF conductors leads to stronger RF coupling. This compensates for the larger wall losses occurring in the narrower region of the sector. The inventors have found that at any given pressure and spacing between the conductive rods and the plasma, there is spacing between rods that creates optimum power transfer efficiency. The inventors have also found that there is no benefit to spacing the rods closer together than this value and in fact, may decrease the coupling efficiency.

The spacing 260 between the conductive rods 240 of some embodiments is a function of the width W of the pie-shaped plasma source 80 at the point that the conductive rod 240 extends therethrough. Meaning that, as the conductive rods move further from the central axis of the chamber, the width of the plasma source 80 increases, so the spacing 260 between the rods 240 also increases. In one or more embodiments, the inductively coupled plasma has a substantially uniform plasma density between the narrow inner peripheral edge 224 and the wider outer peripheral edge 222. As used in this specification and the appended claims, the term “substantially uniform” means that there is less than a 50% relative difference in the plasma density across the width and length of the plasma region 220. Stated differently, the density of conductive rods 240 is greater toward the inner peripheral edge 224 of the pie-shaped plasma source 80 than at the outer peripheral edge 222.

FIG. 8 shows another embodiment in which the RF conductors form an oblique angle with respect to the walls 226 of the pie-shaped sector. The RF conductors also form an oblique angle with respect to the arcuate path or motion of the wafer 60. The angled rods allow a longer rod to be positioned within the sector, although there may be a smaller number of total rods. The inventors have found that the oblique orientation of the rods can allow the length of the rods to be controlled to obtain excellent coupling between the rod and plasma. The oblique angle of orientation may also provide a decrease in the non-uniformity of the plasma.

Additional embodiments of the invention are directed to methods of processing a plurality of substrates. The plurality of substrates is loaded onto substrate support in a processing chamber. The substrate support is rotated to pass each of the plurality of substrates across a gas distribution assembly to deposit a film on the substrate. The substrate support is rotated to move the substrates to a plasma region adjacent an inductively coupled pie-shaped plasma source generating a substantially uniform plasma in the plasma region. These steps are repeated until a film of desired thickness is formed.

Rotation of the carousel can be continuous or discontinuous. In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where it can pause again. Pausing between the injectors may provide time for additional processing steps between each layer deposition (e.g., exposure to plasma).

The frequency of the plasma may be tuned depending on the specific reactive species being used. Suitable frequencies include, but are not limited to, 2 MHz, 13.56 MHz, 40 MHz, 60 MHz and 100 MHz.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus are disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

During processing, the substrate can be heated or cooled. Such heating or cooling can be accomplished by any suitable means including, but not limited to, changing the temperature of the substrate support (e.g., susceptor) and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

While the foregoing is directed to embodiments of the present invention, other and further embodiments of the invention may be devised without departing from the basic scope thereof, and the scope thereof is determined by the claims that follow.

1. A processing chamber comprising:
at least one inductively coupled pie-shaped plasma source positioned along an arcuate path in the processing chamber to generate an inductively coupled plasma in a plasma region adjacent the plasma source, the pie-shaped plasma source having a narrow width at an inner peripheral edge and a larger width at an outer peripheral edge, the pie-shaped plasma source comprising a plurality of conductive rods within the inductively coupled plasma source, the inductively coupled plasma having a substantially uniform plasma density between the narrow inner peripheral edge and the wider outer peripheral edge; and
a substrate support apparatus within the processing chamber, the substrate support apparatus rotatable around a central axis of the processing chamber to move at least one substrate along the arcuate path adjacent the at least one pie-shaped plasma source.

2. The processing chamber of claim 1, wherein the conductive rods are radially spaced apart and extend along the width of the inductively coupled pie-shaped plasma source.

3. The processing chamber of claim 2, wherein the spacing between the conductive rods is a function of the width of the pie-shaped plasma source that the conductive rod extends through.

4. The processing chamber of claim 3, wherein a density of conductive rods is greater toward the inner peripheral edge of the pie-shaped plasma source than at the outer peripheral edge.

5. The processing chamber of claim 1, wherein the plurality of conductive rods comprise a single rod that repeatedly passes through the pie-shaped plasma source.

6. The processing chamber of claim 1, wherein each of the conductive rods is a separate rod.

7. The processing chamber of claim 1, wherein the plurality of conductive rods extend at an oblique angle with respect to radial walls of the pie-shaped plasma source, each conductive rod extending through a length of the pie-shaped plasma source.

8. The processing chamber of claim 1, wherein the pie-shaped plasma source further comprises a dielectric layer between the plurality of conductive rods and a region in which a plasma is formed.

9. The processing chamber of claim 8, wherein the dielectric layer comprises quartz.

10. The processing chamber of claim 1, further comprising a plurality of gas distribution assemblies spaced around the central axis of the processing chamber and positioned above the substrate support apparatus.

11. The processing chamber of claim 10, wherein there are a plurality of inductively coupled pie-shaped plasma sources alternating with the plurality of gas distribution assemblies so that a substrate moving along the arcuate path would be sequentially exposed to a gas distribution assembly and plasma source.

12. A processing chamber comprising:
a plurality of pie-shaped gas distribution assemblies spaced about the processing chamber so that there is a region between each of the gas distribution assemblies, each of the pie-shaped gas distribution assemblies having an inner peripheral edge and an outer peripheral edge and a plurality of elongate gas ports extending from near the inner peripheral edge to near the outer peripheral edge and having a larger width at the outer peripheral edge than at the inner peripheral edge, the plurality of gas ports comprising a first reactive gas port and second reactive gas port so that a substrate passing the gas distribution assembly will be subjected to, in order, the first reactive gas port and the second reactive gas port to deposit a layer on the substrate;
a plurality of inductively coupled pie-shaped plasma sources spaced about the processing chamber so that at least one inductively coupled pie-shaped plasma source is between each of the plurality of pie-shaped gas distribution assemblies, the inductively coupled pie-shaped plasma sources to generate an inductively coupled plasma in a plasma region adjacent the plasma source, the pie-shaped plasma sources having a narrow width at an inner peripheral edge and a larger width at an outer peripheral edge, each of the pie-shaped plasma sources comprising one or more of a plurality of conductive rods passing through the plasma source and a single conductive rod repeatedly passing through the plasma source; and
a susceptor comprising a plurality of recesses to support a plurality of substrates, the susceptor rotatable in a circular path adjacent each of the plurality of gas distribution assemblies and the plurality of inductively coupled pie-shaped plasma sources,
wherein the inductively coupled plasma in the plasma region has a substantially uniform plasma density near the narrow inner peripheral edge and the wider outer peripheral edge.

13. The processing chamber of claim 12, wherein the plurality of conductive rods are radially spaced apart and extend along the width of the inductively coupled pie-shaped plasma source, wherein the spacing between the conductive rods is a function of the width of a portion of the pie-shaped plasma source that the conductive rod extends through.

14. The processing chamber of claim 13, wherein a density of conductive rods is greater toward the inner peripheral edge of the pie-shaped plasma source than at the outer peripheral edge.

15. A method of processing a plurality of substrates, the method comprising:
(a) loading a plurality of substrates onto a substrate support in a processing chamber;
(b) rotating the substrate support to pass each of the plurality of substrates across a gas distribution assembly to deposit a film on the substrate;
(c) rotating the substrate support to move the substrates to a plasma region adjacent an inductively coupled pie-shaped plasma source generating a substantially uniform plasma in the plasma region; and
(d) repeated (b) and (c) to form a film of desired thickness.

16. The processing chamber of claim 10, wherein each of the gas distribution assemblies comprises a plurality of elongate gas ports extending in a direction substantially perpendicular to the arcuate path traversed by the at least one substrate, the plurality of gas ports comprising a first reactive gas port and a second reactive gas port so that a substrate passing the gas distribution assemblies will be subjected to, in order, the first reactive gas port and the second reactive gas port to deposit a layer on the substrate.

17. The processing chamber of claim 1, wherein the substrate support apparatus comprises a susceptor assembly.

18. The processing chamber of claim 17, wherein the susceptor comprises a plurality of recesses sized to support a substrate.

19. The processing chamber of claim 18, wherein the recesses are sized so that a top surface of the substrate is substantially coplanar with a top surface of the susceptor.

20. A cluster tool comprising:
a central transfer station comprising a robot to move substrates between the central transfer station and one or more of a load lock chamber and a processing chamber; and
at least one processing chamber according to claim 12.
